(19) United States
(12) Patent Application Publication
(10) Pub. No.: US 2025/0157786 A1
(43) Pub. Date: May 15, 2025

(54) Charged Particle Beam Apparatus

(71) Applicant: Hitachi, Ltd., Tokyo (JP)

(72) Inventors: Fumiaki ICHIHASHI, Tokyo (JP); Toshiaki TANIGAKI, Tokyo (JP)

(21) Appl. No.: 18/940,959

(22) Filed: Nov. 8, 2024

(30) Foreign Application Priority Data
Nov. 15, 2023 (JP) 2023-194099

(51) Int. Cl. H01J 37/22; H01J 37/26

(52) U.S. Cl. CPC H01J 37/224; H01J 37/222; H01J 37/265; H01J 2237/223; H01J 2237/2614

(57) ABSTRACT

A charged particle beam apparatus includes: an electron source that irradiates a membrane-type holder with an electron beam; a deflector that changes an angle of incidence of the electron beam; a camera that is exposed to the electron beam transmitted through the membrane-type holder; and a control unit that controls the electron source, the deflector, and the camera. The control unit obtains an exposure image by continuously exposing the camera to the electron beam while changing the angle of incidence of the electron beam focused on any one of a first layer, a second layer, and a third layer included in the membrane-type holder.

### CLAIM OF PRIORITY

The present application claims priority from Japanese Patent Application JP 2023-194099 filed on Nov. 15, 2023, the content of which is hereby incorporated by reference into this application.

### BACKGROUND OF THE INVENTION

### 1. Field of the Invention

The present invention relates to a charged particle beam apparatus.

### 2. Description of Related Art

A charged particle beam apparatus, as typified by a transmission electron microscope, obtains an observation image of a sample by irradiating the sample with an electron beam accelerated at high voltage. Although it is common for the charged particle beam apparatus to observe the sample placed in a vacuum, in order to elucidate a reaction mechanism of a catalyst used in a fuel cell or the like, it is necessary to observe a sample placed in a gas or a liquid.

US2015/348745A discloses an embodiment in which a gas or a liquid is sealed in a membrane-type holder having an enclosed room formed by a membrane, and a sample placed in the gas or the liquid is observed.

However, US2015/348745A does not take into consideration the effect of the membrane that forms the enclosed room on the observation image. The electron beam with which the sample is irradiated is transmitted through not only the sample but also the membranes above and below the sample. Therefore, the observation image includes a signal originating from the sample and a signal originating from the membrane. As a result, the signal originating from the membrane may deteriorate the image quality of the observation image.

### SUMMARY OF THE INVENTION

An object of the present invention is to provide a charged particle beam apparatus capable of suppressing deterioration in image quality of an observation image obtained using a membrane-type holder.

To achieve the above-mentioned object, a charged particle beam apparatus according to an embodiment of the invention includes: an electron source that irradiates a membrane-type holder with an electron beam; a deflector that changes an angle of incidence of the electron beam; a camera that is exposed to the electron beam transmitted through the membrane-type holder; and a control unit that controls the electron source, the deflector, and the camera, in which the control unit obtains an exposure image by continuously exposing the camera to the electron beam while changing the angle of incidence of the electron beam focused on any one of a first layer, a second layer, and a third layer included in the membrane-type holder.

According to the embodiment of the present invention, it is possible to provide a charged particle beam apparatus capable of suppressing deterioration in image quality of an observation image obtained using a membrane-type holder.

### BRIEF DESCRIPTION OF THE DRAWINGS

FIG. 1 is a schematic configuration diagram of a transmission electron microscope as an example of a charged particle beam apparatus;

FIG. 2 is a diagram illustrating an example of a membrane-type holder;

FIG. 3 is a diagram illustrating an example of a flow of processing according to Embodiment 1;

FIG. 4 is a diagram illustrating an example of a screen for setting electron beam tilt conditions;

FIG. 5A is a diagram illustrating an angle of incidence of an electron beam;

FIG. 5B is a diagram illustrating an azimuthal angle of the electron beam;

FIG. 6 is a diagram illustrating an example of the electron beam tilt conditions;

FIG. 7 is a diagram illustrating an example of a screen for displaying an exposure image;

FIG. 8 is a diagram illustrating another example of the electron beam tilt conditions;

FIG. 9 is a diagram illustrating another example of the electron beam tilt conditions;

FIG. 10 is a diagram illustrating another example of the electron beam tilt conditions;

FIG. 11 is a schematic configuration diagram of a transmission electron microscope for electron beam holography as an example of the charged particle beam apparatus;

FIG. 12 is a diagram illustrating an example of a flow of processing according to Embodiment 2;

FIG. 13 is a diagram illustrating an example of a screen for setting electron beam tilt conditions; and

FIG. 14 is a diagram illustrating an example of image processing.

### DESCRIPTION OF EMBODIMENTS

Hereinafter, a charged particle beam apparatus according to an embodiment of the present invention will be described, with reference to the drawings. The charged particle beam apparatus is a transmission electron microscope, a scanning electron microscope, a focused ion beam apparatus, or the like that generates an observation image of a sample by irradiating the sample with a charged particle beam such as an electron beam. In the following, the transmission electron microscope will be described as an example of the charged particle beam apparatus. In addition, in the following description and accompanying drawings, duplicated description of components having the same functional configuration is omitted by applying the same reference numerals and signs. Further, in order to indicate the orientation of each drawing, the XYZ coordinate system is added to each drawing.

### Embodiment 1

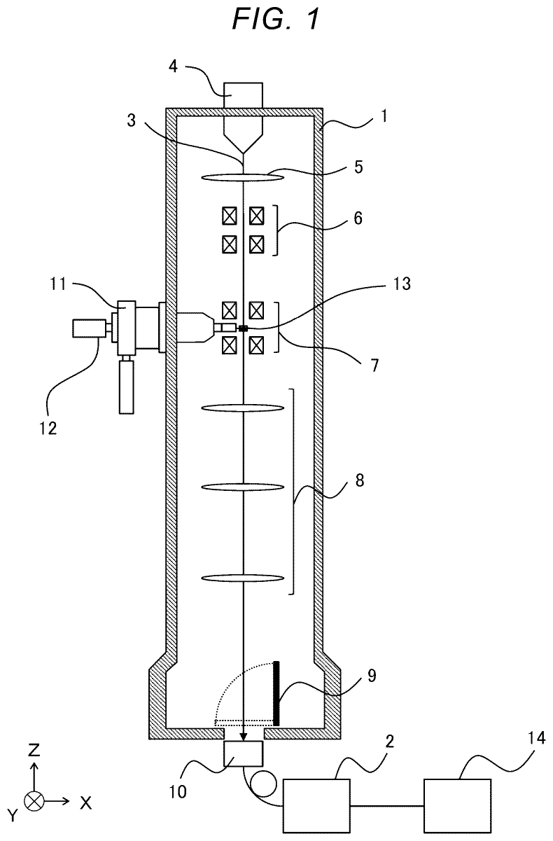

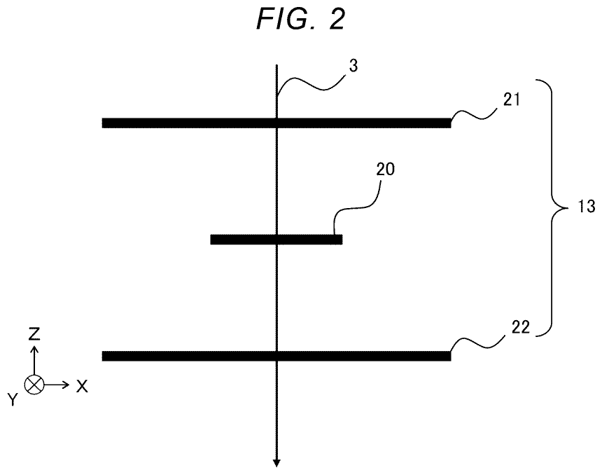

A transmission electron microscope 1 according to Embodiment 1 will be described with reference to FIG. 1. The transmission electron microscope 1 has an electron source 4, a focusing lens 5, a deflector 6, an objective lens 7, an imaging lens 8, a fluorescent plate 9, a camera 10, a goniometer 11, an image display unit 14, and a control unit 2. A sample holder 12 having a membrane-type holder 13 at the front end is inserted into the goniometer 11. A structure of the membrane-type holder 13 will be described later with reference to FIG. 2.

The electron source 4 includes a cathode that emits an electron beam 3, with which the membrane-type holder 13 is irradiated, and an accelerating tube that accelerates the electron beam 3. The focusing lens 5 is a lens that adjusts a size of the electron beam 3 with which the membrane-type holder 13 is irradiated. The deflector 6 changes an angle of incidence of the electron beam 3 with which the membrane-type holder 13 is irradiated. The objective lens 7 is a lens that adjusts focus of the electron beam 3 with which the membrane-type holder 13 is irradiated. The imaging lens 8 is a lens that forms an image of electrons transmitted through the membrane-type holder 13 on the fluorescent plate 9 or the camera 10. The fluorescent plate 9 is a plate that emits fluorescent light in a case where electrons that have passed through the imaging lens 8 are incident on the plate. The camera 10 captures an image of the fluorescent light emitted by the fluorescent plate 9 and the electrons that have passed through the imaging lens 8. The goniometer 11 is a mechanism that moves the inserted sample holder 12 in the direction of the X axis and that rotates the sample holder 12 around an axis parallel to the X axis. It should be noted that the goniometer 11 may be removed, and an insertion hole into which the sample holder 12 is inserted may be provided instead of the goniometer 11. The image display unit 14 is a liquid crystal display or the like that displays the observation image captured by the camera 10. The control unit 2 is a device that controls each unit and that is, for example, a computer.

The membrane-type holder 13 will be described with reference to FIG. 2. The membrane-type holder 13 has an upper membrane 21 and a lower membrane 22 and holds a sample 20 while sealing a gas or a liquid in an enclosed room formed by the upper membrane 21 and the lower membrane 22. The electron beam 3, with which the membrane-type holder 13 is irradiated, is transmitted through not only the sample 20 but also the upper membrane 21 and the lower membrane 22. Therefore, the observation image, which is displayed on the image display unit 14, includes signals originating from the upper membrane 21 and the lower membrane 22 and a signal originating from the sample 20. In a case of observing the sample 20, the signals originating from the upper membrane 21 and the lower membrane 22 are noise, which deteriorates the image quality of the observation image of the sample 20.

In Embodiment 1, the camera 10 is continuously exposed to the electron beam while the angle of incidence of the electron beam 3 focused on the sample 20 is changed. Thereby, by dispersing noise signals originating from the upper membrane 21 and the lower membrane 22, deterioration in image quality of the observation image of the sample 20 is suppressed. The upper membrane 21 may be referred to as a first layer, the sample 20 may be referred to as a second layer, and the lower membrane 22 may be referred to as a third layer.

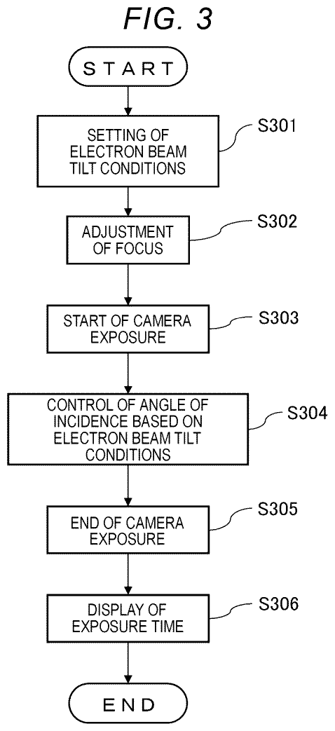

An example of a flow of processing according to Embodiment 1 will be described step by step with reference to FIG. 3.

### (S301)

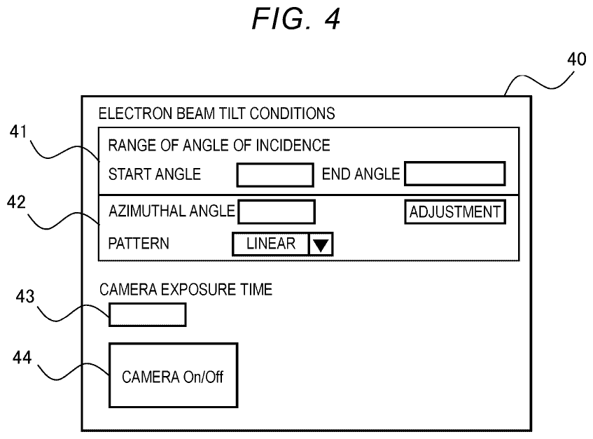

An operator sets electron beam tilt conditions. For example, a tilt condition setting screen 40 illustrated in FIG. 4 is used for setting the electron beam tilt conditions. The tilt condition setting screen 40 has an incidence angle range setting section 41, an azimuthal angle setting section 42, an exposure time setting section 43, and a camera button 44.

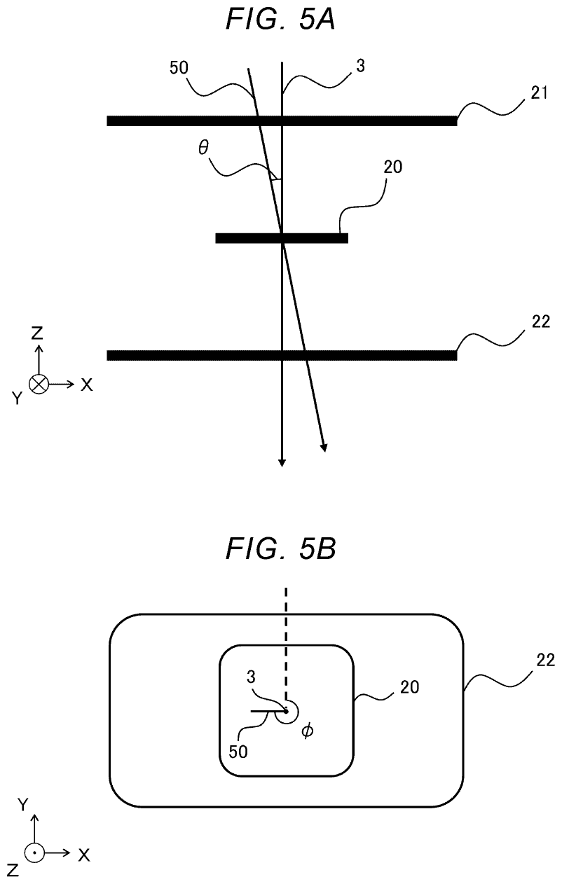

In the incidence angle range setting section 41, a range, within which the angle of incidence of the electron beam 3 changes, is set. The angle of incidence is an angle with respect to the electron beam 3 in a case where a signal which is input to the deflector 6 is zero and is an angle θ formed by the tilted electron beam 50 and the electron beam 3 as exemplified in FIG. 5A. The range, within which the angle of incidence is changed, is set by inputting a start angle and an end angle to the incidence angle range setting section 41.

In the azimuthal angle setting section 42, an azimuthal angle, which indicates the direction in which the angle of incidence is changed, is set. The azimuthal angle is an angle with respect to a predetermined direction, for example, an angle q formed by a Y axis direction and the tilted electron beam 50 as illustrated in FIG. 5B.

In the exposure time setting section 43, a time for the continuous exposure of the camera 10 is set. The camera button 44 is pressed in a case of starting the continuous exposure by the camera 10 or in a case of ending the continuous exposure.
(S302)

The operator adjusts the focus of the electron beam 3 such that the sample 20 is brought into focus. By bringing the sample 20 into focus, it is not necessary to move a position, at which the observation image of the sample 20 is formed, even in a case of changing the angle of incidence of the electron beam 3. The electron beam 3 may be focused on the upper membrane 21 or the lower membrane 22. An autofocus function may be used in adjustment of the focus.
(S303)

The control unit 2 starts the continuous exposure using the camera 10. For example, the continuous exposure starts in a case where the camera button 44 is pressed.
(S304)

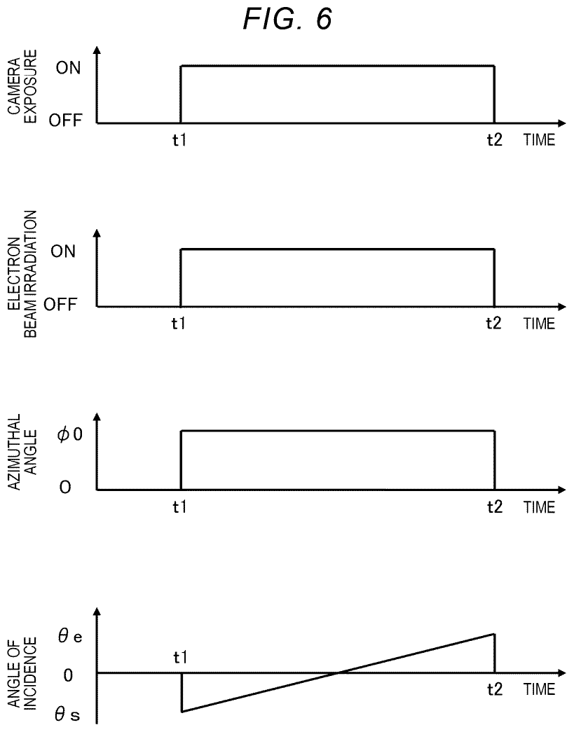

The control unit 2 controls the angle of incidence of the electron beam 3 based on the electron beam tilt conditions set in S301. An example of the electron beam tilt conditions will be described with reference to FIG. 6. In FIG. 6, in a case where the camera exposure is turned on at time t1, the electron beam irradiation is also turned on. Then, the angle of incidence is changed from θs to θe at a constant speed in a state where the azimuthal angle is kept at φ0, and the camera exposure and the electron beam irradiation are turned off at time t2. It should be noted that since aberration may be caused by the change in angle of incidence of the electron beam, it is preferable that the aberration is corrected in accordance with the angle of incidence.
(S305)

The control unit 2 ends the continuous exposure using the camera 10. For example, the continuous exposure ends in a case where the time, which is set in the exposure time setting section 43, has elapsed after the camera button 44 is pressed in S303. It should be noted that the continuous exposure also ends in a case where pressing of the camera button 44 is detected before the set exposure time has elapsed.
(S306)

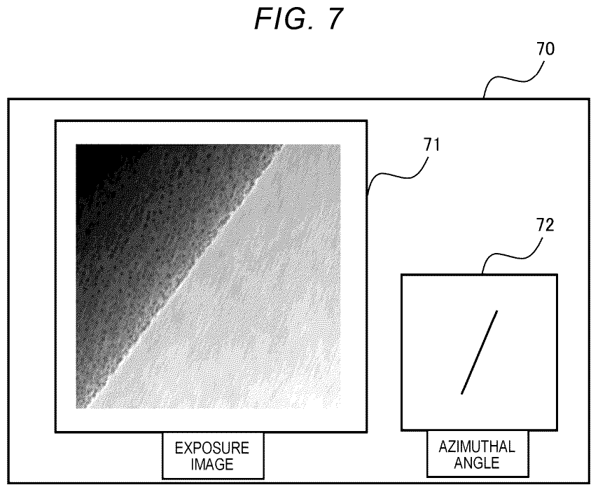

The control unit 2 causes the image display unit 14 to display an exposure image captured through the continuous exposure of the camera 10. For example, the image display unit 14 displays an image display screen 70 illustrated in FIG. 7. The image display screen 70 has an exposure image display section 71 and an azimuthal angle display section 72.

In the exposure image display section 71, the exposure image is displayed. The exposure image illustrated in FIG. 7 is an observation image of the end portion of the sample 20. The exposure image is acquired by changing the angle of incidence of the electron beam 3 based on the electron beam tilt conditions in FIG. 6 from the start of the continuous exposure in S303 to the end of the continuous exposure in S305. The dark region in the upper left is a region in which the electron beam has passed through the sample 20, the upper membrane 21, and the lower membrane 22. The bright region in the lower right is the region in which the electron beam has passed through the upper membrane 21 and the lower membrane 22. The exposure image in FIG. 7 is an image obtained by performing the continuous exposure while changing the angle of incidence. Therefore, multiple stripes originating from the membrane may be seen in parallel to the direction in which the angle of incidence changes. However, since the noise signal originating from the membrane is dispersed and averaged, there is no problem in observing the sample 20 in the dark region.

In the azimuthal angle display section 72, the line segment indicates the direction of the azimuthal angle which is set in S301. By indicating the direction of the azimuthal angle together with the exposure image, the operator is able to determine whether the multiple stripes in the exposure image are caused by the change in the angle of incidence.

According to the flow of processing illustrated in FIG. 3, by continuously exposing the camera 10 while changing the angle of incidence of the electron beam focused on the sample 20, it is possible to obtain an exposure image in which noise signals originating from the upper membrane 21 and the lower membrane 22 are dispersed. Although the acquired exposure image includes multiple stripes originating from the membrane caused by the change in angle of incidence, it is possible to clearly observe the sample 20. In addition, it is possible to obtain an image equivalent to the exposure image by synthesizing the observation images captured at each different angle of incidence. However, it is possible to eliminate the processing of synthesizing the observation images for each different angle of incidence by performing the continuous exposure while changing the angle of incidence. Further, the electron beam tilt conditions are not limited to examples illustrated in FIG. 6.

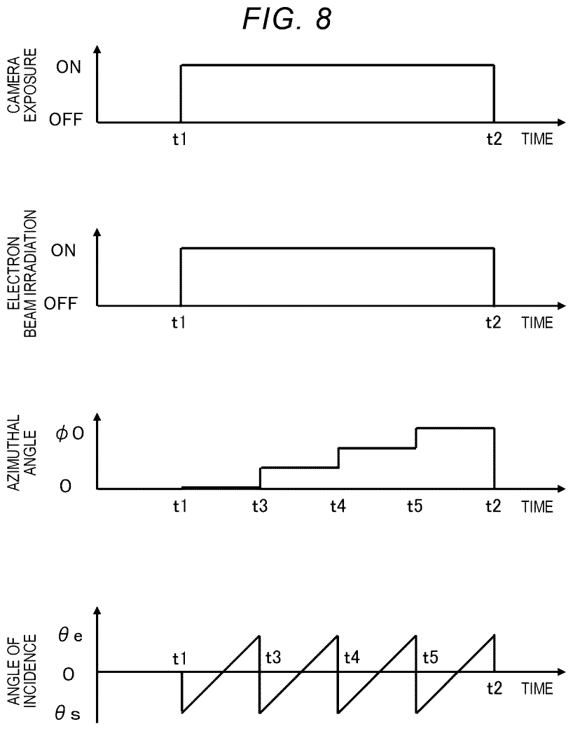

Another example of the electron beam tilt condition will be described with reference to FIG. 8. In FIG. 8, in a case where the camera exposure is turned on at time t1, the electron beam irradiation is also turned on, and the angle of incidence is changed from Os to de at a constant speed in a state where the azimuthal angle is kept constant until time t3. Then, the azimuthal angle is switched at times t3, t4, and t5, and the angle of incidence is changed from θs to θe at a constant speed until the azimuthal angle is switched. According to the electron beam tilt condition of FIG. 8, there are multiple directions in which the angle of incidence of the electron beam is changed. Therefore, multiple stripes caused by the change in angle of incidence are dispersed and averaged in the directions of multiple azimuthal angles, thereby improving the image quality of the exposure image.

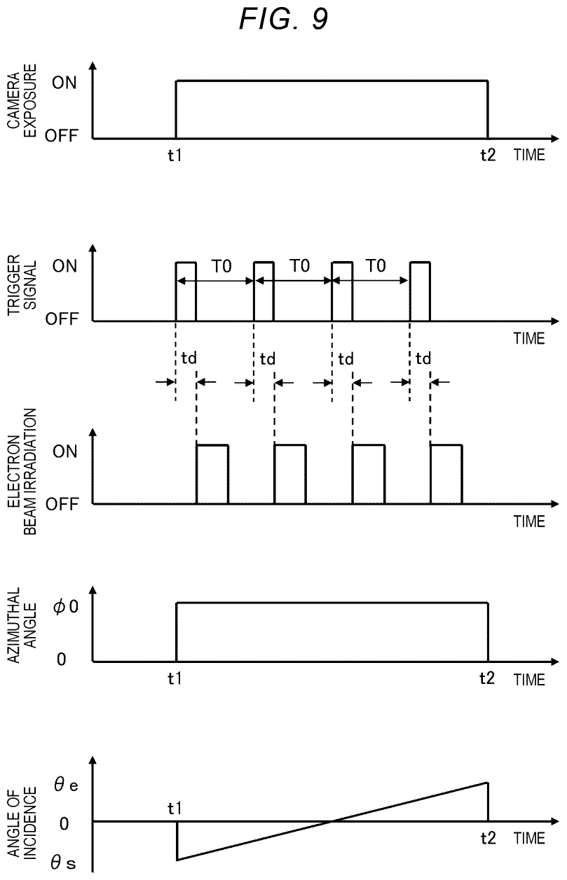

Another example of the electron beam tilt condition will be described with reference to FIG. 9. FIG. 9 illustrates the time-resolved electron microscopy according to Embodiment 1. That is, while the camera exposure is turned on from time t1 to t2 and the angle of incidence is changed from θs to θe at a constant speed in a state where the azimuthal angle is kept at φ0, the electron beam is emitted as a pulse with a delay time td for a trigger signal generated at period TO. The trigger signal is generated based on the timing of supplying a gas or a liquid to the membrane-type holder 13, irradiating the sample 20 with light, or applying a voltage. The exposure image obtained under the electron beam tilt conditions in FIG. 9 is generated by superimposing the transmitted electrons in a case where the electron beam is emitted as a pulse. Then, since the angle of incidence of the electron beam is changing during the electron beam pulse irradiation, an exposure image in which noise signals originating from the membrane are dispersed is acquired.

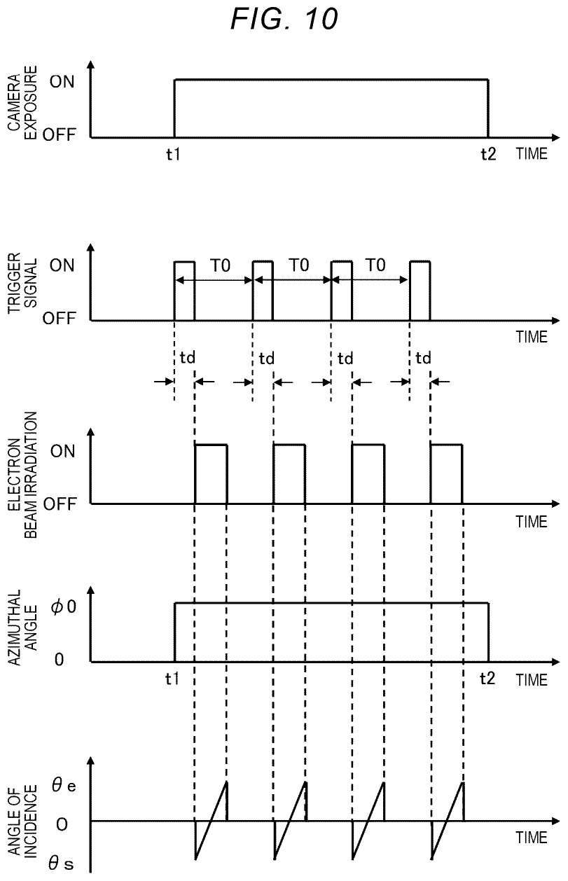

Another example of the electron beam tilt condition will be described with reference to FIG. 10. FIG. 10 illustrates the time-resolved electron microscopy according to Embodiment 1, as in FIG. 9. In FIG. 10, the angle of incidence is changed from θs to θe at a constant speed in each section where the electron beam is emitted as a pulse. According to the electron beam tilt conditions in FIG. 10, the range, in which the angle of incidence is changed in each section where the electron beam is emitted as a pulse, is wider than the range in FIG. 9. Therefore, the noise signal originating from the membrane is dispersed, and the image quality of the exposure image is improved.

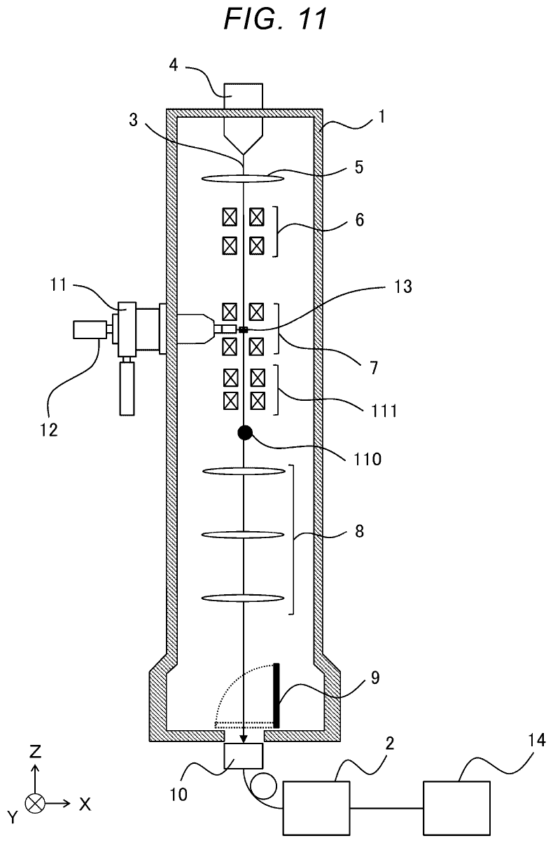

It should be noted that Embodiment 1 can also be applied to charged particle beam apparatuses other than the transmission electron microscope 1 illustrated in FIG. 1. A transmission electron microscope for the electron beam holography will be described with reference to FIG. 11. The transmission electron microscope 1 illustrated in FIG. 11 is configured by adding an electron beam biprism 110 and a swing-back deflector 111 to the configuration of FIG. 1.

The electron beam biprism 110 obtains a hologram image by making interference between an object wave passing through an object and a reference wave passing through a vacuum. It should be noted that the position of the electron beam biprism 110 is not limited to the position illustrated in FIG. 11 and may be under the deflector 6.

The swing-back deflector 111 deflects the electron beam such that the electron beam is incident on the electron beam biprism 110 even in a case where the angle of incidence of the electron beam is changed. That is, the swing-back deflector 111 is disposed between the deflector 6 and the electron beam biprism 110 and is linked to the operation of the deflector 6.

By applying Embodiment 1 to the transmission electron microscope for the electron beam holography, it is possible to obtain a hologram image in which noise signals originating from the membrane are reduced.

### Embodiment 2

In Embodiment 1, a description was given of how to obtain an exposure image in which the noise signals originating from the membrane are dispersed by continuously exposing the camera 10 while changing the angle of incidence of the electron beam 3 focused on the sample 20. The exposure image obtained in Embodiment 1 includes the multiple stripes originating from the membrane caused by the change in angle of incidence. In Embodiment 2, a description is given of how to reduce the multiple stripes originating from the membrane through image processing. It should be noted that the same components as those in Embodiment 1 are represented by the same reference numerals and signs to simplify the description.

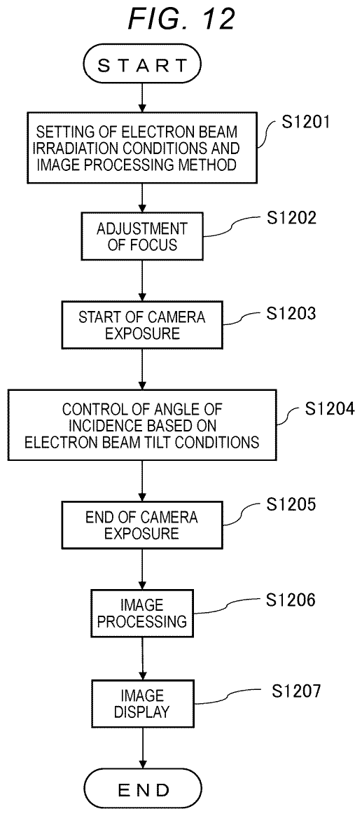

An example of a flow of processing according to Embodiment 2 will be described step by step with reference to FIG. 12.
(S1201)

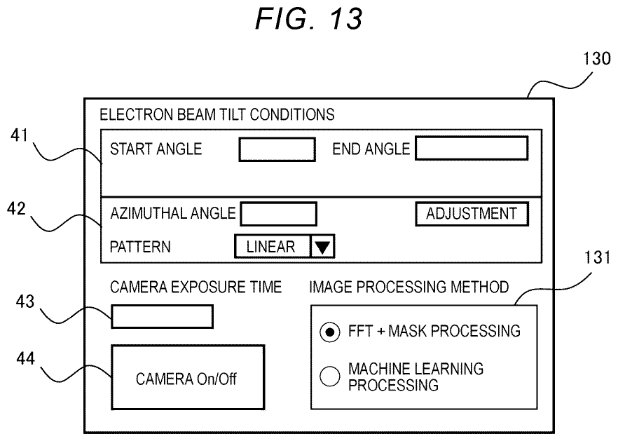

The operator sets the electron beam tilt conditions and the image processing method. For example, a setting screen 130 illustrated in FIG. 13 is used for setting the electron beam tilt conditions and the image processing method. The setting screen 130 illustrated in FIG. 13 is a screen in which an image processing setting section 131 is added to the tilt condition setting screen 40 in FIG. 4. In the image processing setting section 131, a method of image processing to be performed on the exposure image is selected from among options. It should be noted that the image processing setting section 131 in FIG. 13 illustrates options of “FFT+mask processing” and “machine learning processing”, and “FFT+mask processing” is selected.
(S1202) to (S1205)

S1202 to S1205 are the same as S302 to S305 in FIG. 3. It should be noted that in S1205, an exposure image is acquired by performing continuous exposure using the camera 10 while changing the angle of incidence of the electron beam 3.
(S1206)

The control unit 2 performs the image processing, which is selected in S1201, on the exposure image acquired in S1205.

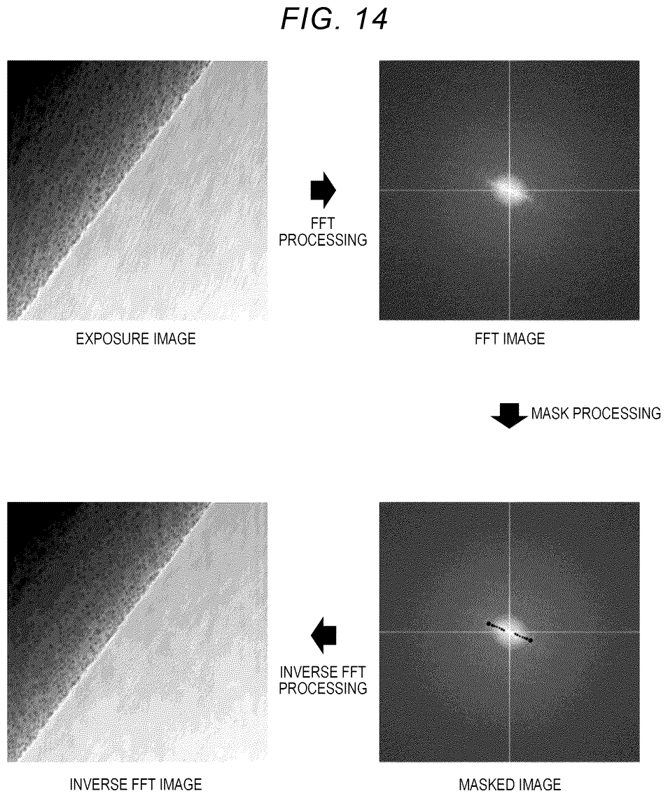

“FFT+mask processing” will be described with reference to FIG. 14. The exposure image acquired in S1205 includes multiple stripes originating from the membrane caused by the change in angle of incidence. Therefore, an FFT image is generated by performing fast Fourier transform (FFT) processing on the exposure image, and streaks corresponding to the stripes are made visible.

The FFT image is an image in which the intensity of spatial frequency is expressed as a luminance. Here, the horizontal axis of the image indicates a horizontal spatial frequency and the vertical axis of the image indicates a vertical spatial frequency. The spatial frequency at the center coordinates of the image is zero and increases toward the edge. In the FFT image in FIG. 14, the streaks corresponding to the multiple stripes included in the exposure image appear around the center coordinates in a range from the upper left to the lower right.

Next, mask processing is performed to add a mask to the FFT image. Therefore, the streaks corresponding to the multiple stripes included in the exposure image are removed from the FFT image, and a masked image is generated. In the masked image in FIG. 14, a plurality of black circles superimposed on the streaks are shown as the mask.

Then, inverse FFT processing is performed on the masked image to generate an inverse FFT image in which the multiple stripes originating from the membrane are reduced. In the inverse FFT image in FIG. 14, the multiple stripes included in the exposure image are reduced.

In a case where “machine learning processing” is selected in S1201, the noise signal originating from the membrane is reduced from the exposure image through a machine learning processing section generated in advance by learning multiple training images. Each of the training images used to generate the machine learning processing section is an image obtained by synthesizing an observation image of the sample 20 placed in a vacuum with an observation image of the membrane-type holder 13 which does not include the sample 20. The noise signal originating from the membrane may also be reduced from the exposure image by the machine learning processing section generated by learning without the training images.

The image obtained by the “machine learning processing” has higher image quality than the image obtained by the “FFT+mask processing”. On the other hand, in the “FFT+mask processing”, since it is not necessary to generate the machine learning processing section in advance, it is possible to save the capacity of the storage device.
(S1207)

The control unit 2 displays the image, which is subjected to the image processing in S1206, on the image display unit 14.

According to the flow of processing illustrated in FIG. 12, the multiple stripes, which originate from the membrane included in the exposure image obtained by performing the continuous exposure while changing the angle of incidence of the electron beam, are reduced through the image processing. As a result, the sample 20 can be observed more clearly.

The above description has been given of the plurality of embodiments of the present invention. The present invention is not limited to the above-mentioned embodiments, and the components can be modified and embodied without departing from the scope of the present invention. Further, a plurality of components disclosed in the above-mentioned embodiments may be appropriately combined. Furthermore, some components may be removed from all the components illustrated in the above-mentioned embodiments.

What is claimed is:

1. A charged particle beam apparatus comprising:
an electron source that irradiates a membrane-type holder with an electron beam;
a deflector that changes an angle of incidence of the electron beam;
a camera that is exposed to the electron beam transmitted through the membrane-type holder; and
a control unit that controls the electron source, the deflector, and the camera,
wherein the control unit obtains an exposure image by continuously exposing the camera to the electron beam while changing the angle of incidence of the electron beam focused on any one of a first layer, a second layer, and a third layer included in the membrane-type holder.

2. The charged particle beam apparatus according to claim 1, wherein
the control unit performs image processing on the exposure image.

3. The charged particle beam apparatus according to claim 2, wherein
the control unit generates an FFT image by performing Fourier transform processing on the exposure image, generates a masked image by performing mask processing on the FFT image, and generates an inverse FFT image by performing inverse Fourier transform processing on the masked image.

4. The charged particle beam apparatus according to claim 2, wherein
the control unit generates an image in which a noise signal originating from a membrane is reduced by performing machine learning processing on the exposure image.

5. The charged particle beam apparatus according to claim 4, wherein
the machine learning processing is performed through a machine learning processing section generated by learning an image, in which an observation image of a sample placed in a vacuum and an observation image of the membrane-type holder are synthesized, as a training image.

6. The charged particle beam apparatus according to claim 1, wherein
the control unit displays an azimuthal angle indicating a direction in which the angle of incidence is changed, together with the exposure image.

7. The charged particle beam apparatus according to claim 1, wherein
the control unit obtains the exposure image by setting a plurality of azimuthal angles indicating a direction in which the angle of incidence is changed and changing the angle of incidence for each azimuthal angle.

8. The charged particle beam apparatus according to claim 1, wherein
the control unit obtains the exposure image by emitting the electron beam as a pulse based on a periodically emitted trigger signal and changing the angle of incidence from a start angle to an end angle in each section in which the electron beam is emitted as a pulse.

9. The charged particle beam apparatus according to claim 1, further comprising:
an electron beam biprism that obtains a hologram image by making interference between an object wave passing through an object and a reference wave passing through a vacuum.
